(19) United States
(12) Patent Application Publication
(10) Pub. No.: US 2025/0341600 A1
(43) Pub. Date: Nov. 6, 2025

(54) MULTISPECTRAL MAGNETIC RESONANCE IMAGING ENHANCEMENT USING SPECTRAL ACQUISITION REDUNDANCY

(71) Applicant: The Medical College of Wisconsin, Inc., Milwaukee, WI (US)

(72) Inventors: Nikolai Jonas Mickevicius, Milwaukee, WI (US); Kevin Matthew Koch, Milwaukee, WI (US); Andrew Scott Nencka, Milwaukee, WI (US)

(21) Appl. No.: 18/864,266

(22) PCT Filed: May 8, 2023
(86) PCT No.: PCT/US2023/021336

§ 371 Date: Nov. 8, 2024

Related U.S. Application Data
(60) Provisional application No. 63/339,481, filed on May 8, 2022.

(51) Int. Cl. G01R 33/56; G01R 33/485; G01R 33/563; G01R 33/565

(52) U.S. Cl. CPC G01R 33/5608; G01R 33/485; G01R 33/5602; G01R 33/5607; G01R 33/5635; G01R 33/56536

(57) ABSTRACT

Multispectral magnetic resonance image data having multiple different contrast weightings (e.g., T1 weighting, T2 weighting, proton density weighting, inversion recovery weighting) are acquired in a single data acquisition. Different sets of multispectral data are acquired using an interleaved acquisition, in which data with different contrast weightings are acquired at different interleaved sets of spectral bins. Additionally or alternatively, frequency-encoding gradient polarity can be reversed for different interleaves in order to perform residual artifact compensation.

### CROSS-REFERENCE TO RELATED APPLICATIONS

This application claims the benefit of U.S. Provisional Patent Application Ser. No. 63/339,481, filed on May 8, 2022, and entitled “MULTISPECTRAL MAGNETIC RESONANCE IMAGING ENHANCEMENT USING SPECTRAL ACQUISITION REDUNDANCY,” which is herein incorporated by reference in its entirety.

### BACKGROUND

When performing magnetic resonance imaging (“MRI”) near metallic implants using a multispectral imaging (“MSI”) technique, the scans can be broken up into several spectral bins, where a full 3D image is acquired at a unique off-resonance frequency. This overall approach results in more signal near the metal implant and reduced image warping due to the implant-induced magnetic field gradients. One implementation of MSI, known as the MAVRIC approach, utilizes overlapping spectral profiles with smooth transition regions.

### SUMMARY OF THE DISCLOSURE

The present disclosure addresses the aforementioned drawbacks by providing a method for multispectral magnetic resonance imaging (“MRI”). The method includes acquiring multispectral data from a subject using an MRI system, where the subject has a metal object implanted therein. Acquiring the multispectral data includes acquiring first multispectral data with a first contrast weighting at a first set of spectral bins each corresponding to a different resonance frequency offset, and acquiring second multispectral data with a second contrast weighting at a second set of spectral bins each corresponding to a different resonance frequency offset. The second set of spectral bins is interleaved with the first set of spectral bins. First spectral bin images are reconstructed from the first multispectral data, where the first spectral bin images depict the first contrast weighting; and second spectral bin images are reconstructed from the second multispectral data, where the second spectral bin images depict the second contrast weighting. A first composite image is generated from the first spectral bin images, where the first composite image has the first contrast weighting and reduced metal artifacts from the metal object; and a second composite image is generated from the second spectral bin images, where the second composite image has the second contrast weighting and reduced metal artifacts from the metal object.

It is another aspect of the present disclosure to provide a method for multispectral MRI. The method includes acquiring multispectral data from a subject using an MRI system, where the subject has a metal object implanted therein. Acquiring the multispectral data includes acquiring first multispectral data using positive polarity frequency-encoding gradients and at a first set of spectral bins each corresponding to a different resonance frequency offset; and acquiring second multispectral data using negative polarity frequency-encoding gradients and at a second set of spectral bins each corresponding to a different resonance frequency offset, where the second set of spectral bins is interleaved with the first set of spectral bins. First spectral bin images are reconstructed from the first multispectral data, and second spectral bin are reconstructed images from the second multispectral data. A composite image is generated from the first and second spectral bin images, where the composite image has reduced residual metal artifacts associated with the metal object.

It is another aspect of the present disclosure to provide a method for multispectral MRI. The method includes acquiring multispectral data from a subject using an MRI system, where the subject has a metal object implanted therein. Acquiring the multispectral data includes acquiring a plurality of different multispectral datasets, each with a different contrast weighting, where spectral bins associated with each multispectral dataset are interleaved with spectral bins associated with other ones of the multispectral datasets in a spectral domain. A plurality of different sets of spectral bin images are reconstructed from the multispectral datasets, each set of spectral bin images being reconstructed from a different one of the multispectral datasets such that each set of spectral bin images has one of the different contrast weightings. A plurality of composite images are then generated, each composite image being generated from one of the sets of spectral bin images such that each different composite image has one of the different contrast weightings, each of the composite images having reduced metal artifacts from the metal object.

The foregoing and other aspects and advantages of the present disclosure will appear from the following description. In the description, reference is made to the accompanying drawings that form a part hereof, and in which there is shown by way of illustration one or more embodiments. These embodiments do not necessarily represent the full scope of the invention, however, and reference is therefore made to the claims and herein for interpreting the scope of the invention.

### BRIEF DESCRIPTION OF THE DRAWINGS

FIG. 1 depicts overlapping spectral bins used to excite a spin isochromat in a multispectral imaging (“MSI”) acquisition.

FIG. 2 shows a transformation along the x-axis of FIG. 1 to convert spin isochromat precessional frequency to central bin excitation frequency (i.e., the frequency offset of each bin excitation).

FIG. 3A illustrates an example of interleaved sets of spectral bins including a first set of spectral bins that is interleaved with a second set of spectral bins. The different sets of spectral bins can be used to acquire data with different contrast weightings, using reversed frequency-encoding gradient polarities, or both.

FIG. 3B illustrates estimating multispectral data for a spectral bin not acquired in a set of interleaves using other data acquired in that set of interleaves.

FIG. 4 is an example three-dimensional (“3D”) fast spin echo (“FSE”) pulse sequence that may be used to acquire multispectral data in accordance with some examples described in the present disclosure.

FIG. 5 is a flowchart setting forth the steps of an example method for MSI using interleaved sets of spectral bins for accelerated multi-contrast imaging, reduced residual metal artifact processing based on reversed gradient polarity acquisitions, or both.

FIG. 6 is a block diagram of an example MRI system that can implement the methods described in the present disclosure.

### DETAILED DESCRIPTION

Described here are systems and methods for acquiring multispectral magnetic resonance image data having multiple different contrast weightings (e.g., T1 weighting, T2 weighting, proton density weighting, inversion recovery weighting) in a single data acquisition. In general, multispectral data are acquired using an interleaved acquisition, which different interleaves acquiring data with different contrast weightings. Advantageously, the disclosed systems and methods utilize these overlapping spectral acquisitions to collect multiple image contrast weighting within a single acquisition. Additionally or alternatively, frequency-encoding gradient polarity can be reversed for different interleaves in order to perform residual artifact compensation.

In general, the systems and methods described in the present disclosure improve the efficiency and performance of 3D-MSI techniques, as deployed for metal artifact suppression across multiple different clinical applications, including orthopedic imaging, neurological imaging, and/or spinal imaging. Advantageously, the disclosed systems and methods can provide a twofold or greater acceleration of data acquisition (e.g., by acquiring images with multiple different contrast weightings in a single acquisition), significantly reduced residual metal artifacts, or both, compared to existing 3D-MSI techniques.

As noted above, it is an aspect of the systems and methods described in the present disclosure to acquire multispectral data using an interleaved acquisition. In particular, different interleaves of spectral images (or bins) are acquired independently. Because the spectral profiles of an interleaved multispectral acquisition are overlapped, a known relationship between the spectral interleaves can be used to “fill in” spectral information that is otherwise missed in a given acquisition.

Using the systems and methods described in the present disclosure, multispectral data are acquired using an MRI system. The multispectral data are acquired by sampling two or more different contrast weightings in a single acquisition, such that the multispectral data include first multispectral data having a first contrast weighting and second multispectral data having a second contrast weighting. In particular, data pertaining to different contrast weightings are acquired during different interleaves of a multispectral imaging (“MSI”) acquisition. For instance, a first contrast weighting can be acquired in a first interleave (or set of interleaves) and a second contrast weighting can be acquired in a second interleave (or set of interleaves).

As a non-limiting example, the first contrast weighting can be a proton density weighting, such that first data acquired in the first interleave (or set of interleaves) include proton density weighted data, and the second contrast weighting can be a short tau inversion recovery (“STIR”) contrast weighting, such that second data acquired in the second interleave (or set of interleaves) include STIR-weighted data. For instance, for the purposes of multi-contrast generation, a two-interleave MAVRIC acquisition can be utilized to collect proton density-weighted spectral bins in one interleave and then STIR contrast bins in the second interleave. In other examples, the first contrast weighting and the second contrast weighting can include other contrast weightings, such as other T1-weighted contrast, T2-weighted contrasts, or the like.

The magnetic susceptibility differences between metallic implants and surrounding bone and tissues range between hundreds and thousands of parts per million (“ppm”). Accordingly, the induced Larmor frequency offsets, δᵥ_{₀}=γδB₀, near implants approach 12-15 kHz at 1.5 T, and 24-30 kHz at 3 T.

In MSI data acquisitions, overlapping Gaussian spectral bin profiles are often used. These overlapping Gaussian spectral windows, G_{b}(v), are constructed such that,

$$\begin{matrix}{\sum }_{b = 1}^{{N}_{b}} {G}_{b} ( v ) \approx 1 & \begin{matrix} \\ ∀ v\end{matrix}\end{matrix} ; \qquad ( 1 )$$

where b is the spectral bin index and V is the frequency offset. This condition ensures that a homogeneous response is maintained when the spectral bins are combined to form a composite image.

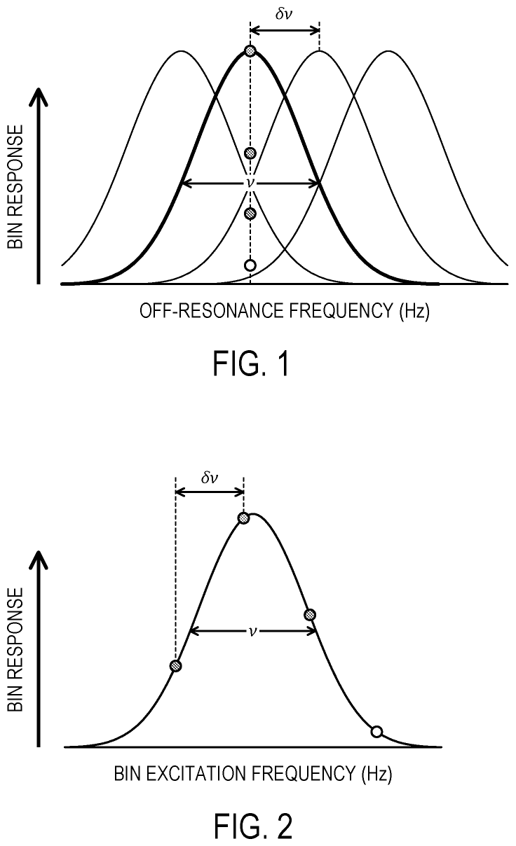

Consider a set of spectral bins in the spectral domain,

$$f ( {v}_{bin} ) {\vert}_{x , y , z} = {I}_{b} ( x , y , z , {v}_{bin} ) ; \qquad ( 2 )$$

where v_{bin} is the central frequency-offset of a given spectral bin. Typically, a conventional MSI (e.g., a MAVRIC) dataset will provide 3-5 spectral data points per image voxel. FIG. 1 illustrates an example construction of such spectral domain data. The off-resonance location of a given spin isochromat is indicated in FIG. 1. Overlapping excitation profiles that excite this isochromat are also depicted. The spectral domain, displayed in FIG. 2, is the transformation of the x-axis of FIG. 1 from isochromat off-resonance frequency to bin-excitation-frequency. Here, the bin intensity is plotted against the center excitation frequency of each bin. These bin intensities follow a Gaussian trend that ideally mimics the applied RF excitation profile.

In an MSI acquisition, multiple spectrally unique subimages, which may be referred to as spectral bin images, can be acquired in a single acquisition, a single repetition time (“TR”) period, or the like. Moreover, these spectral bin images can be acquired in an interleaved manner.

It is an advantage of the systems and methods described in the present disclosure that different spectral interleaves can be acquired with different contrast weightings. As a non-limiting example, multispectral data can be acquired using a pulse sequence that includes multiple echo trains (e.g., Carr-Purcell-Meiboom-Gill (“CPMG”) echo trains) within a single TR period. Each echo train can sample a different spectral range, or spectral bin. Spectral bins are centered on a frequency offset, V, and are separated by δv, as shown in FIG. 1. Values of the frequency offset, v, can be updated for each echo train as integer multiples, nᵢ, of δv, for i=1, N] with N being the number of echo trains that can be acquired within a single TR period.

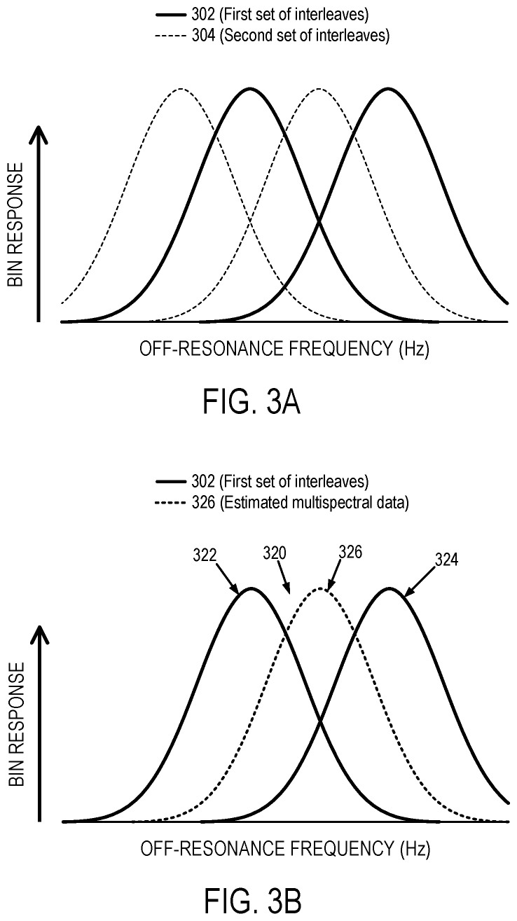

An example acquisition scheme is illustrated in FIG. 3A. In this example, a first set of multispectral data is acquired using a first set of interleaved spectral bins 302, and a second set of multispectral data is acquired using a second set of interleaved spectral bins 304. The first set of multispectral data is acquired with a first contrast weighting type (e.g., proton density weighting), while the second set of multispectral data is acquired with a second contrast weighting (e.g., STIR-weighting, T1 weighting, T2 weighting, or the like). As an example, an interleaved multispectral data acquisition with a 1 kHz resonance interval, δv, in the range −7 kHz to +7 kHz may have the following order: [−7, 1, −5, 3, −3, 5, −1, 7, −6, 0, −4, 6, −2, 4, 2 kHz], with the first set of interleaves corresponding to [−7, −5, −3, −1,−6, −4, −2 kHz] and the second set of interleaves corresponding to [1, 3, 5, 7, 0, 6, 4, 2 kHz]. As another example, the interleaved multispectral data acquisition with a 1 kHz resonance interval, δv, in the range −7 kHz to +7 kHz may have the following order: [−7, −6, −5, −4, −3, −2, −1, 0, 1, 2, 3, 4, 5, 6, 7 kHz], with the first set of interleaves corresponding to [−7, −5, −3, −1, 1, 3, 5, 7 kHz] and the second set of interleaves corresponding to [−6, −4, −2, 0, 2, 4, 6 kHz]. Although FIG. 3A illustrates two sets of interleaves, it will be appreciated that in other implementations more than two sets of interleaves may be used, such as three sets of interleaves, four sets of interleaves, and so on.

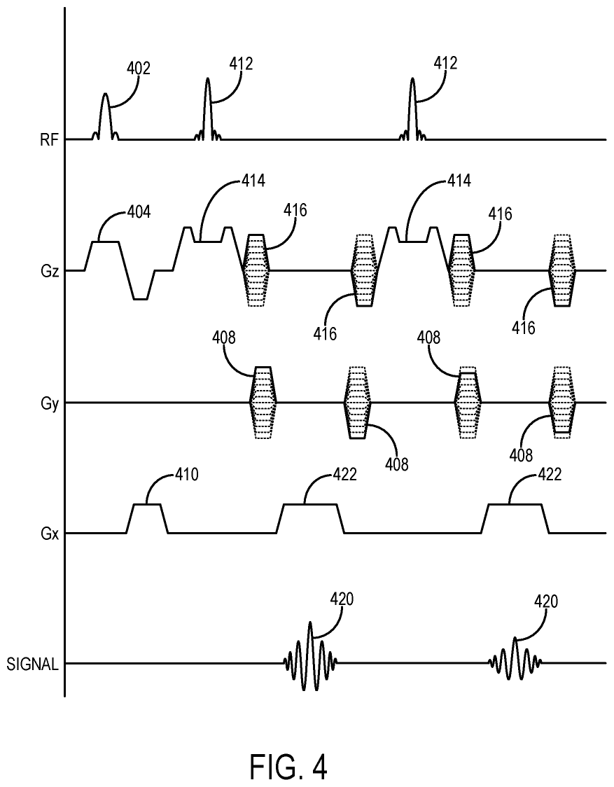

FIG. 4 illustrates an example 3D fast spin echo (“FSE”) pulse sequence 400 that can be used to acquire multispectral data. The pulse sequence 400 includes an RF excitation pulse 402 that is generated in the presence of a slab-select gradient 404 to provide transverse magnetization in a single slab containing a plurality of contiguous slices through the patient. This transverse magnetization is refocused by each of two or more RF refocusing pulses 412 generated in the presence of a slab-select gradient 414 to produce spin echo signals 420 that are acquired in the presence of readout gradient pulses 422. A prephasing gradient 410 may also be applied along the same gradient axis as the readout gradient pulses 422. Each spin echo signal 420 is separately phase encoded by respective phase encoding pulses 408 along a first phase encoding direction (e.g., the ky-direction) and by phase encoding pulses 416 along a second phase encoding direction (e.g., the kz-direction). The magnitude of each phase encoding pulse is different, and it is stepped through values to acquire separate views during a complete scan.

As described above, the pulse sequence 400 may be played out to acquire multispectral data corresponding to different sets of interleaved spectral bins. For instance, the pulse sequence 400 may acquire multispectral data for the first set of interleaves by changing the frequency of the RF excitation pulse 402 in each repetition based on the spectral frequency offsets in the first set of interleaves. The pulse sequence 400 may then be repeated to acquire multispectral data for the second set of interleaves by changing the frequency of the RF excitation pulse 402 in each repetition based on the spectral frequency offsets in the second set of interleaves while also changing one or more acquisition parameters (e.g., echo time, repetition time) and/or adding magnetization preparation pulses (e.g., inversion recovery pulses) to provide a different contrast weighting for the second set of multispectral data. Additionally or alternatively, a different pulse sequence with a different contrast weighting mechanism may also be utilized to acquired the second set of multispectral data.

In some embodiments, the interleaved spectral bins are spaced apart by a sufficient distance so as to avoid saturation of signal in adjacent bins. For example, excitation or refocusing of one spectral bin can overlap with the excitation or refocusing of another spectral bin within the same set of interleaves.

In some embodiments, the interleaved spectral bins are acquired with opposite magnetic field gradient polarities during readout. For example, a first set of interleaves can be acquired with positive frequency-encoding gradient polarities, and a second set of interleaves can be acquired with negative frequency-encoding magnetic field gradient polarities. For instance, the pulse sequence 400 shown in FIG. 4 can be repeated to acquire multispectral data for the first set of interleaves by changing the frequency of the RF excitation pulse 402 in each repetition based on the spectral frequency offsets in the first set of interleaves. The pulse sequence 400 may then be repeated with different acquisition parameters to result in a different contrast weighting, or a different pulse sequence with a different contrast weighting mechanism may be played out, to acquire multispectral data for the second set of interleaves by changing the frequency of the RF excitation pulse 402 in each repetition based on the spectral frequency offsets in the second set of interleaves while also changing the polarity of the readout gradients 422. For instance, if the polarity of the readout gradients 422 is positive (e.g., as illustrated in FIG. 4) when acquiring the first set of multispectral data, then the polarity of the readout gradients 422 may be set to negative when acquiring the second set of multispectral data. For the purposes of residual artifact reduction, reversing the polarity of the frequency-encoding magnetic field gradients (e.g., the readout gradients 422) can provide differing residual artifacts in images. When two separate images are collected with opposing polarities, the two images can be used together to produce an image with substantially reduced residual metal artifacts. As one example, the two images may be subtracted

Based on spectral redundancy and/or a known relationship between the interleaved acquisitions, gaps between the spectral bins for different contrast weightings can be estimated after data acquisition. As a non-limiting example, a spectral model can then be incorporated into the image reconstruction process to formulate the full set of spectral bins for each contrast weighting utilizing the known spectral relationship between the interleaved acquisitions. For instance, as illustrated in FIG. 3B, the spectral gap 320 between a first spectral bin 322 and a second spectral bin 324 in the first set of interleaves 302 can be estimated. This estimated spectral data 326 provides an estimate of spectral information at the frequency offset and within the corresponding spectral bin missing from the first set of interleaves 302, but with the contrast weighting of the other data acquired in the first set of multispectral data.

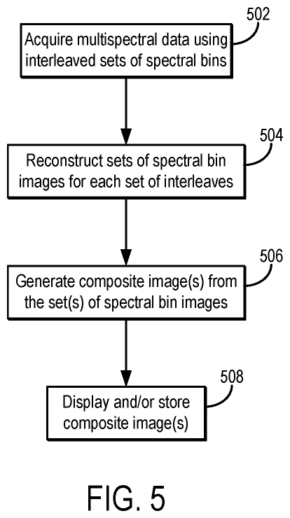

Referring now to FIG. 5, a flowchart is illustrated as setting forth the steps of an example method for acquiring multispectral data using an MRI system, where the multispectral data are acquired using an interleaved acquisition such that data acquired at different interleaves have different contrast weightings.

The method includes acquiring multispectral data with an MRI system, as indicated at step 502. As noted above, the multispectral data are acquired with a pulse sequence and data acquisition scheme in which data in different spectral bins are acquired in an interleaved manner within a single acquisition. Different interleaved spectral bins are acquired with different contrast weightings, such that the multispectral data represent multi-contrast data over a range of spectral bands. For instance, the multispectral data can be acquired with a first set of interleaves having a first contrast weighting and a second set of interleaves having a second contrast weighting. In other embodiments, more than two sets of interleaves and/or more than two types of contrast weightings can be acquired. For example, the multispectral data may include three different sets of interleaves, four different sets of interleaves, etc. In these instances, the multispectral data may include first multispectral data acquired at the first set of interleaves with a first contrast weighting, second multispectral data acquired at the second set of interleaves with a second contrast weighting, third multispectral data acquired at the third set of interleaves with a third contrast weighting, and so on. The different contrast weightings can include two or more of proton density weighting, T1 weighting, T2 weighting, inversion recovery weighting (e.g., STIR weighting, FLAIR weighting), diffusion weighting, perfusion weighting, and so on.

In some embodiments, the multispectral data can be acquired using a pulse sequence that includes multiple echo trains, where each echo train corresponds to a spectral bin. The spectral bins sampled by each echo train are ordered according to a planned interleaving schedule, as described above. As one non-limiting example, the pulse sequence may be a fast spin echo pulse sequence, such as the 3D FSE pulse sequence illustrated in FIG. 4.

Additionally or alternatively, the multispectral data can include data acquired using opposite magnetic field gradient polarities for different sets of interleaves. For instance, the first set of interleaves can be acquired with a first magnetic field gradient polarity (e.g., a positive polarity) and the second set of interleaves can be acquired with a second magnetic field gradient polarity (e.g., a negative polarity). That is, in some embodiments, the multispectral data can include different sets of data acquired at different sets of interleaves, each having a different contrast weighting. In some other embodiments, the multispectral data can includes different sets of data acquired at different sets of interleaves, with different set of interleaves being acquired using different magnetic field gradient (e.g., frequency-encoding gradient) polarities. In still other embodiments, different sets of data can be acquired at different sets of interleaves with different contrast weightings, using different gradient polarities, and combinations thereof.

Spectral bin images are then reconstructed from the multispectral data, as indicated at step 504. A set of spectral bin images is reconstructed for each set of interleaves, such that each set of spectral bin images corresponds to one of the different contrast weightings. For example, when the multispectral data include first multispectral data acquired at a first set of interleaves with a first contrast weighting, and a second set of multispectral data acquired at a second set of interleaves with a second contrast weighting, the spectral bins images will include a first set of spectral bin images reconstructed from the first multispectral data and having the first contrast weighting and a second set of spectral bin images reconstructed from the second multispectral data and having the second contrast weighting.

As indicated above, the spectral bin images can be reconstructed using a model of the spectral relationship between the different sets of interleaves in order to estimate spectral information corresponding to the gaps in each set of interleaves. In this way, additional multispectral data can be estimated, such that the reconstructed spectral bin images will correspond to a larger number of spectral bins than were acquired in the multispectral data. For instance, when a first set of interleaves corresponds to spectral bins [−2, 0, 2 kHz] and a second set of interleaves corresponds to spectral bins [−1, 1 kHz], the first set of spectral bin images can be reconstructed from the first multispectral data using a model that estimates the spectral content at the spectral bins [−1, 1 kHz] with the first contrast weighting. Likewise, the second set of spectral bin images can be reconstructed from the second multispectral data using a model that estimates the spectral content at the spectral bins [−2, 0, 2 kHz] with the second contrast weighting.

Additionally or alternatively, the spectral bin images can be reconstructed using a model of the spectral relationship between the different sets of interleaves in order to reduce residual metal artifacts in the reconstructed images. For instance, when a first set of multispectral data corresponds to data acquired using positive frequency-encoding gradients and a second set of multispectral data corresponds to data acquired using negative frequency-encoding gradients, images can be reconstructed with reduced residual metal artifacts.

Composite images are then generated from the spectral bin images, as indicated at step 506. For instance, for the aforementioned example with first and second sets of spectral bin images, a first composite image having the first contrast weighting can be generated from the first set of spectral bin images and a second composite image having the second contrast weighting can be generated from the second set of spectral bin images. Each composite image can be generated using a maximum intensity projection, a sum-of-squares, or other suitable method for combining the spectral bin images. The different composite images can then be displayed to a user, stored for later use, or both, as indicated at step 508.

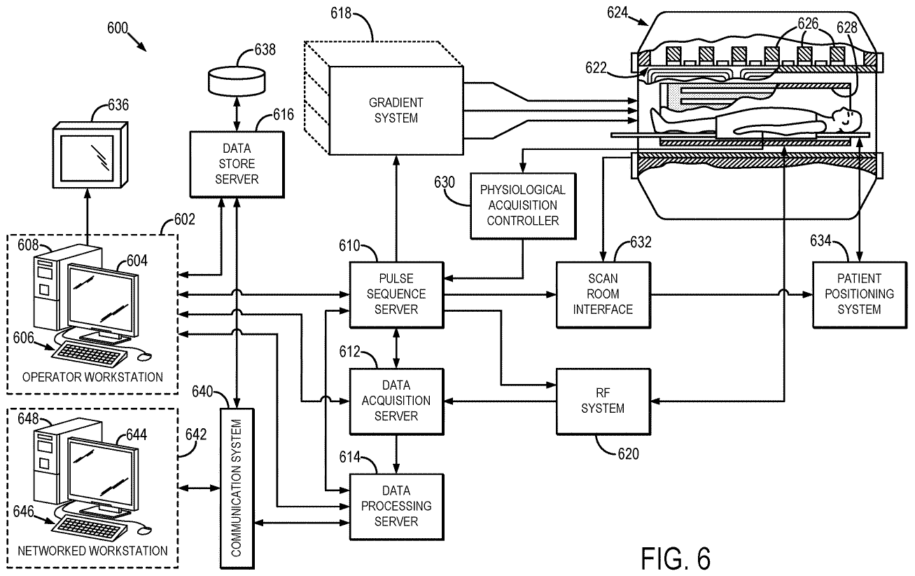

Referring particularly now to FIG. 6, an example of an MRI system 600 that can implement the methods described here is illustrated. The MRI system 600 includes an operator workstation 602 that may include a display 604, one or more input devices 606 (e.g., a keyboard, a mouse), and a processor 608. The processor 608 may include a commercially available programmable machine running a commercially available operating system. The operator workstation 602 provides an operator interface that facilitates entering scan parameters into the MRI system 600. The operator workstation 602 may be coupled to different servers, including, for example, a pulse sequence server 610, a data acquisition server 612, a data processing server 614, and a data store server 616. The operator workstation 602 and the servers 610, 612, 614, and 616 may be connected via a communication system 640, which may include wired or wireless network connections.

The pulse sequence server 610 functions in response to instructions provided by the operator workstation 602 to operate a gradient system 618 and a radiofrequency (“RF”) system 620. Gradient waveforms for performing a prescribed scan are produced and applied to the gradient system 618, which then excites gradient coils in an assembly 622 to produce the magnetic field gradients Gₓ, G_{y}, and G_{z}, that are used for spatially encoding magnetic resonance signals. The gradient coil assembly 622 forms part of a magnet assembly 624 that includes a polarizing magnet 626 and a whole-body RF coil 628.

RF waveforms are applied by the RF system 620 to the RF coil 628, or a separate local coil to perform the prescribed magnetic resonance pulse sequence. Responsive magnetic resonance signals detected by the RF coil 628, or a separate local coil, are received by the RF system 620. The responsive magnetic resonance signals may be amplified, demodulated, filtered, and digitized under direction of commands produced by the pulse sequence server 610. The RF system 620 includes an RF transmitter for producing a wide variety of RF pulses used in MRI pulse sequences. The RF transmitter is responsive to the prescribed scan and direction from the pulse sequence server 610 to produce RF pulses of the desired frequency, phase, and pulse amplitude waveform. The generated RF pulses may be applied to the whole-body RF coil 628 or to one or more local coils or coil arrays.

The RF system 620 also includes one or more RF receiver channels. An RF receiver channel includes an RF preamplifier that amplifies the magnetic resonance signal received by the coil 628 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} ;$$

and the phase of the received magnetic resonance signal may also be determined according to the following relationship:

$$φ = {tan}^{- 1} ( \frac{Q}{I} ) .$$

The pulse sequence server 610 may receive patient data from a physiological acquisition controller 630. By way of example, the physiological acquisition controller 630 may receive signals from a number of different sensors connected to the patient, including electrocardiograph (“ECG”) signal from electrodes, or respiratory signals from a respiratory bellows or other respiratory monitoring devices. These signals may be used by the pulse sequence server 610 to synchronize, or “gate,” the performance of the scan with the subject's heart beat or respiration.

The pulse sequence server 610 may also connect to a scan room interface circuit 632 that receives signals from various sensors associated with the condition of the patient and the magnet system. Through the scan room interface circuit 632, a patient positioning system 634 can receive commands to move the patient to desired positions during the scan.

The digitized magnetic resonance signal samples produced by the RF system 620 are received by the data acquisition server 612. The data acquisition server 612 operates in response to instructions downloaded from the operator workstation 602 to receive the real-time magnetic resonance data and provide buffer storage, so that data is not lost by data overrun. In some scans, the data acquisition server 612 passes the acquired magnetic resonance data to the data processor server 614. In scans that require information derived from acquired magnetic resonance data to control the further performance of the scan, the data acquisition server 612 may be programmed to produce such information and convey it to the pulse sequence server 610. For example, during pre-scans, magnetic resonance data may be acquired and used to calibrate the pulse sequence performed by the pulse sequence server 610. As another example, navigator signals may be acquired and used to adjust the operating parameters of the RF system 620 or the gradient system 618, or to control the view order in which k-space is sampled. In still another example, the data acquisition server 612 may also process magnetic resonance signals used to detect the arrival of a contrast agent in a magnetic resonance angiography (“MRA”) scan. For example, the data acquisition server 612 may acquire magnetic resonance data and processes it in real-time to produce information that is used to control the scan.

The data processing server 614 receives magnetic resonance data from the data acquisition server 612 and processes the magnetic resonance data in accordance with instructions provided by the operator workstation 602. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 614 are conveyed back to the operator workstation 602 for storage. Real-time images may be stored in a data base memory cache, from which they may be output to operator display 602 or a display 636. Batch mode images or selected real time images may be stored in a host database on disc storage 638. When such images have been reconstructed and transferred to storage, the data processing server 614 may notify the data store server 616 on the operator workstation 602. The operator workstation 602 may be used by an operator to archive the images, produce films, or send the images via a network to other facilities.

The MRI system 600 may also include one or more networked workstations 642. For example, a networked workstation 642 may include a display 644, one or more input devices 646 (e.g., a keyboard, a mouse), and a processor 648. The networked workstation 642 may be located within the same facility as the operator workstation 602, or in a different facility, such as a different healthcare institution or clinic.

The networked workstation 642 may gain remote access to the data processing server 614 or data store server 616 via the communication system 640. Accordingly, multiple networked workstations 642 may have access to the data processing server 614 and the data store server 616. In this manner, magnetic resonance data, reconstructed images, or other data may be exchanged between the data processing server 614 or the data store server 616 and the networked workstations 642, such that the data or images may be remotely processed by a networked workstation 642.

The present disclosure has described one or more preferred embodiments, and it should be appreciated that many equivalents, alternatives, variations, and modifications, aside from those expressly stated, are possible and within the scope of the invention.

1. A method for multispectral magnetic resonance imaging (MRI), the method comprising:
(a) acquiring multispectral data from a subject using an MRI system, wherein the subject has a metal object implanted therein and wherein acquiring the multispectral data comprises:
acquiring first multispectral data with a first contrast weighting at a first set of spectral bins each corresponding to a different resonance frequency offset; and
acquiring second multispectral data with a second contrast weighting at a second set of spectral bins each corresponding to a different resonance frequency offset, wherein the second set of spectral bins is interleaved with the first set of spectral bins;
(b) reconstructing first spectral bin images from the first multispectral data, wherein the first spectral bin images depict the first contrast weighting;
(c) reconstructing second spectral bin images from the second multispectral data, wherein the second spectral bin images depict the second contrast weighting;
(d) generating a first composite image from the first spectral bin images, wherein the first composite image has the first contrast weighting and reduced metal artifacts from the metal object; and
(e) generating a second composite image from the second spectral bin images, wherein the second composite image has the second contrast weighting and reduced metal artifacts from the metal object.

2. The method of claim 1, wherein the first spectral bin images are reconstructed using a model that estimates additional multispectral data with the first contrast weighting at spectral bins corresponding to the second set of spectral bins using a known relationship between the first set of spectral bins and the second set of spectral bins.

3. The method of claim 2, wherein the second spectral bin images are reconstructed using another model that estimates additional multispectral data with the second contrast weighting at spectral bins corresponding to the first set of spectral bins using the known relationship between the first set of spectral bins and the second set of spectral bins.

4. The method of claim 1, wherein the first multispectral data and the second multispectral data are acquired with opposite frequency-encoding gradient polarities.

5. The method of claim 4, wherein the first spectral images and the second spectral images are reconstructed using a model that reduces residual metal artifacts based on the opposite frequency-encoding gradient polarities.

6. The method of claim 4, wherein the first multispectral data are acquired with a positive frequency-encoding gradient polarity and the second multispectral data are acquired with a negative frequency-encoding gradient polarity.

7. The method of claim 1, wherein the first composite image and the second composite image are generated using one of a maximum intensity projection or a sum-of-squares combination.

8. The method of claim 1, wherein the first contrast weighting and the second contrast weighting include at least two of proton density weighting, T1 weighting, T2 weighting, inversion recovery weighting, diffusion weighting, or perfusion weighting.

9. The method of claim 8, wherein one of the first contrast weighting or the second contrast weighting comprises inversion recovery weighting.

10. The method of claim 9, wherein the inversion recovery weighting is a short tau inversion recovery (STIR) contrast weighting.

12. The method of claim 11, wherein the first contrast weighting is proton density weighting and the second contrast weighting is STIR contrast weighting.

13. A method for multispectral magnetic resonance imaging (MRI), the method comprising:
(a) acquiring multispectral data from a subject using an MRI system, wherein the subject has a metal object implanted therein and wherein acquiring the multispectral data comprises:
acquiring first multispectral data using positive polarity frequency-encoding gradients and at a first set of spectral bins each corresponding to a different resonance frequency offset; and
acquiring second multispectral data using negative polarity frequency-encoding gradients and at a second set of spectral bins each corresponding to a different resonance frequency offset, wherein the second set of spectral bins is interleaved with the first set of spectral bins;
(b) reconstructing first spectral bin images from the first multispectral data;
(c) reconstructing second spectral bin images from the second multispectral data;
(d) generating a composite image from the first and second spectral bin images, wherein the composite image has reduced residual metal artifacts associated with the metal object.

14. The method of claim 13, wherein the first spectral images and the second spectral images are reconstructed using a model that reduces residual metal artifacts based on opposite frequency-encoding gradient polarities.

15. A method for multispectral magnetic resonance imaging (MRI), the method comprising:
(a) acquiring multispectral data from a subject using an MRI system, wherein the subject has a metal object implanted therein and wherein acquiring the multispectral data comprises acquiring a plurality of different multispectral datasets, each with a different contrast weighting, wherein spectral bins associated with each multispectral dataset are interleaved with spectral bins associated with other ones of the multispectral datasets in a spectral domain;
(b) reconstructing a plurality of different sets of spectral bin images, each set of spectral bin images being reconstructed from a different one of the multispectral datasets such that each set of spectral bin images has one of the different contrast weightings;
(c) generating a plurality of composite images, each composite image being generated from one of the sets of spectral bin images such that each different composite image has one of the different contrast weightings, each of the composite images having reduced metal artifacts from the metal object.

16. The method of claim 15, wherein a selected one of the plurality of different sets of spectral bin images is reconstructed from a selected one of the multispectral datasets using a model that estimates additional multispectral data at spectral bins not acquired in the selected one of the multispectral datasets.

17. The method of claim 16, wherein the additional multispectral data are estimated using a known relationship between a first set of spectral bins associated with the selected one of multispectral datasets and a second set of spectral bins not associated with the selected one of the multispectral datasets.
